(19) United States
(12) Patent Application Publication
(10) Pub. No.: US 2025/0194013 A1
(43) Pub. Date: Jun. 12, 2025

(54) Cable Impedance Matching Element and Display Device

(71) Applicant: LG Display Co., Ltd., Seoul (KR)

(72) Inventor: Yeonju Kim, Paju-si (KR)

(21) Appl. No.: 18/924,769

(22) Filed: Oct. 23, 2024

(30) Foreign Application Priority Data
Dec. 7, 2023 (KR) 10-2023-0176602

(51) Int. Cl. H05K 1/14

(52) U.S. Cl. CPC H05K 1/14; H05K 2201/0792; H05K 2201/10128

(57) ABSTRACT

Embodiments of the disclosure relate to a cable impedance matching element provided in a flexible cable and, more specifically, may be coupled to an FC and have a blind frame supporting an FC impedance matching element and a plurality of blind blades coupled to at least one side and another side of an edge of the blind frame and may open/close an air layer by tilting of the blind blades.

### CROSS-REFERENCE TO RELATED APPLICATION

This application claims priority from Republic of Korea Patent Application No. 10-2023-0176602, filed on Dec. 7, 2023, which is hereby incorporated by reference in its entirety.

### BACKGROUND

### Field

Embodiments of the disclosure relate to an impedance matching element for cables and a display device.

### Description of Related Art

In general, various electronic devices, such as printers and scanners, often adopt flexible cables as relay cables for various components placed therein. By their excellent flexibility, flexible cables may be used in movable portions as well as fixing portions and, due to low manufacturing costs compared to flexible printed circuit boards (FPCs), are used in a wide range of fields.

Conventionally, such flexible cables are not required to have electrical characteristics such as characteristic impedance. Therefore, the flexible cable is rendered to meet the required specifications by adhering and stacking an insulation film formed of, e.g., polyethylene terephthalate and with adhesive layers attached to two opposite sides of the central conducting line.

Recently, with the development of various electronic products, such as laptop personal computers or digital scanners that realize high-precision image quality, there is a demand for faster signal transmission. Further, as digitalization progresses in other electronic devices, faster signal transmission is inevitably required.

As faster signal transmission is required, the plurality of central conducting lines of the flexible cable need to have different predetermined characteristic impedance values. For example, low characteristic impedance is advantageous for the central conducting line transmitting power voltage and central conducting lines connected to ground, and central conducting lines transmitting predetermined signals are required to have characteristic impedance that impedance-match the input/output terminals transmitting the predetermined signals.

### SUMMARY

Embodiments of the disclosure may provide a cable impedance matching element and a display device including the same.

Embodiments of the disclosure provide a cable impedance matching element that matches the impedance of the flexible cable to be close to the impedance of the printed circuit board to be connected to the flexible cable, and a display device.

Embodiments of the disclosure provide a cable impedance matching element having a simplified driving scheme for impedance matching without negative influence on the arrangement of metal layers provided in the flexible cable by providing an impedance matching element capable of adjusting the impedance of the flexible cable by controlling the tilting angle of blind blades to the flexible cable, and a display device.

Embodiments of the disclosure provide a cable impedance matching element capable of accurately impedance matching by controlling the tilting angle of a plurality of blind blades per number of blind blades or per angle of blind blade according to the capacitance required for the flexible cable, and a display device.

Embodiments of the disclosure provide a cable impedance matching element for minimizing or at least reducing a change in impedance that is caused unintentionally due to a fixing method using a tape or adhesive, by fixing and keeping in shape the impedance matching element in the flexible cable simply with a press-fitting structure without using a table or adhesive, by press-fittingly fixing a hinge portion of a blind frame in a space formed as the flexible cable is folded, and a display device.

Embodiments of the disclosure provide a cable impedance matching element capable of maintaining communication quality while preventing distortions of signal form by impedance matching between elements and mitigating a difference in impedance between elements, and a display device.

A cable impedance matching element according to embodiments of the disclosure may comprise a blind frame coupled to the cable and supporting the cable impedance matching element, and a plurality of blind blades provided between at least one side and another side of an edge of the blind frame to be spaced apart from each other by a predetermined interval, and coupled to be rotatable between the one side and the other side of the blind frame. The blind blades may have an angle from the cable facing the blind blades determined while being rotated through tilting control.

A display device according to embodiments of the disclosure may comprise a display panel where a plurality of data lines and a plurality of gate lines are disposed, and a first printed circuit board supplying a voltage to a data driving circuit driving the data line and a gate driving circuit driving the gate line, a second printed circuit board electrically connected to the first printed circuit board to supply a signal for driving the data driving circuit and the gate driving circuit and a common voltage for driving the panel, and a cable connecting the first printed circuit board and the second printed circuit board. The cable may include a cable impedance matching element to match an impedance of the cable with impedances of the first printed circuit board and the second printed circuit board.

According to embodiments of the disclosure, there may be provided a cable impedance matching element and a display device including the same.

According to embodiments of the disclosure, it is possible to match the impedance of the flexible cable to be close to the impedance of the printed circuit board to be connected, by changing the permittivity characteristic of the flexible cable by having a cable impedance matching element in the flexible cable.

According to embodiments of the disclosure, it is possible to implement a simplified driving scheme for impedance matching without negative influence on the arrangement of metal layers provided in the flexible cable by providing an impedance matching element capable of adjusting the impedance of the flexible cable by controlling the tilting angle of blind blades to the flexible cable.

According to embodiments of the disclosure, it is possible to achieve accurate impedance matching by being able to control the tilting angle of the plurality of blind blades per number of blind blades according to the capacitance required for the flexible cable.

According to embodiments of the disclosure, it is possible to fix and keep in shape the impedance matching element in the flexible cable simply with a press-fitting structure without using a table or adhesive, by press-fittingly fixing a hinge portion of a blind frame in a space formed as the flexible cable is folded. Thus, it is possible to minimize or at least reduce a change in impedance that is caused unintentionally by a fixing method using a tape or an adhesive.

According to embodiments of the disclosure, it is possible to maintain communication quality while preventing or at least reducing distortions of signal form by impedance matching between elements and mitigating a difference in impedance between elements.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is a view schematically illustrating a configuration of a display device according to an embodiment of the disclosure;

FIG. 3 is a plan view illustrating a flexible cable connecting printed circuit boards according to an embodiment of the disclosure;

FIG. 4 is a cross-sectional view illustrating a portion of a cross section of a flexible cable according to an embodiment of the disclosure;

FIG. 5 is a graph illustrating general flexible cable impedance characteristics according to an embodiment of the disclosure;

FIG. 6 is a perspective view illustrating an example of a process of attaching a cable impedance matching element and a flexible cable according to an embodiment of the disclosure;

FIG. 7 illustrates a state before folding after a cable impedance matching element and a flexible cable are attached according to an embodiment of the disclosure;

FIG. 8 is a perspective view illustrating a coupling structure between a cable impedance matching element and a flexible cable according to an embodiment of the disclosure;

FIG. 9 is a plan view illustrating a cable impedance matching element in a blind-off state according to an embodiment of the disclosure;

FIG. 10 is a plan view and a side view illustrating a cable impedance matching element in a blind-on state according to an embodiment of the disclosure;

FIG. 11 is a partially enlarged side view illustrating a cable impedance matching element in a blind-on state according to an embodiment of the disclosure;

FIG. 12 is a graph illustrating a change in impedance characteristics of a flexible cable including a cable impedance matching element according to an embodiment of the disclosure;

FIG. 13 is a graph illustrating a change in permittivity of a flexible cable according to a tilting angle in a blind-on state according to an embodiment of the disclosure; and

FIG. 14 is a graph illustrating an impedance variation width of a flexible cable according to a tilting angle in a blind-on state.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

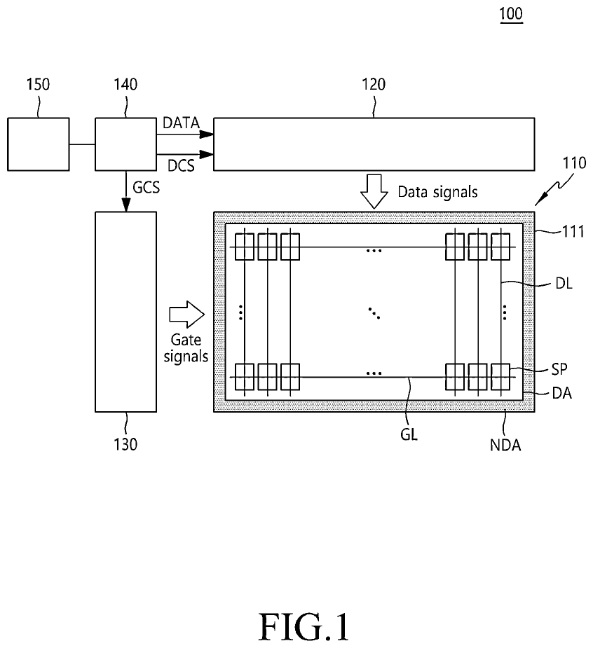

FIG. 1 is a view illustrating a system configuration of a display device according to embodiments of the disclosure.

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA positioned outside the display area DA.

In the display panel 110 according to embodiments of the disclosure, the non-display area NDA may be very small.

For example, the non-display area NDA may include a first non-display area positioned outside the display area DA in a first direction, a second non-display area positioned outside the display area DA in a second direction crossing the first direction, a third non-display area positioned outside the display area DA in a direction opposite to the first direction, and a fourth non-display area positioned outside the display area DA in a direction opposite to the second direction. One or two of the first to fourth non-display areas may include a pad area where the data driving circuit 120 is connected or bonded. Two or three of the first to fourth non-display areas where the pad area is not included may be very small.

As another example, the boundary area between the display area DA and the non-display area NDA may be bent so that the non-display area NDA may be positioned under the display area. In this case, no or little change may be made to the non-display area NDA shown to the user when the user views the display area 100 from the front.

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction.

Here, the first direction may be a column direction and the second direction may be a row direction. The first direction may be the row direction, and the second direction may be the column direction. For convenience of description, described below is an example in which each of the plurality of data lines DL is disposed in the column direction, and each of the plurality of gate lines GL is disposed in the row direction.

The data driving circuit 120 is a circuit for driving the plurality of data lines DL, and may out data signals to the plurality of data lines DL.

The data driving circuit 120 may receive digital image data DATA from the display controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but alternatively, the data driving circuit 120 may be disposed in the display area DA of the display panel 110.

The gate driving circuit 130 is a circuit for driving the plurality of gate lines GL, and may output gate signals to the plurality of gate lines GL. The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110. In the display device 100 according to embodiments of the disclosure, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The display controller 140 is a device for controlling the data driving circuit 120 and the gate driving circuit 130 and may control driving timings for the plurality of data lines DL and driving timings for the plurality of gate lines GL.

The display controller 140 may supply a data driving control signal DCS to the data driving circuit 120 to control the data driving circuit 120 and may supply a gate driving control signal GCS to the gate driving circuit 130 to control the gate driving circuit 130.

The display controller 140 may receive input image data from the host system 150 and supply image data DATA to the data driving circuit 120 based on the input image data.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be mounted on a printed circuit board or a flexible printed circuit and may be electrically connected with the data driving circuit 120 and the gate driving circuit 130 through the printed circuit board or the flexible printed circuit.

The display controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process.

The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit. The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

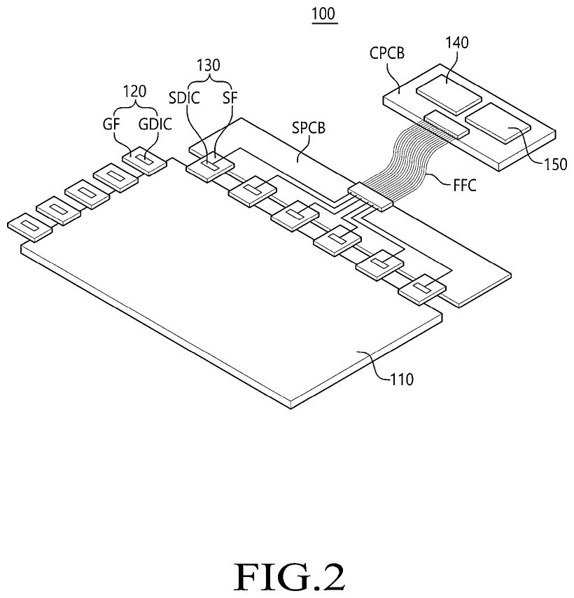

FIG. 2 is a view schematically illustrating a configuration of a display device according to an embodiment of the disclosure.

Referring to FIG. 2, in the display device 100 according to embodiments of the disclosure, the source driving integrated circuit SDIC included in the data driving circuit 120 and the gate driving integrated circuit GDIC included in the gate driving circuit 130 are implemented in the chip-on-film (COF) type among various types (e.g., TAB, COG, or COF).

One or more gate driving integrated circuits GDIC included in the gate driving circuit 130 each may be mounted on a gate film GF, and one side of the gate film GF may be electrically connected with the display panel 110. Lines for electrically connecting the gate driving integrated circuit GDIC and the display panel 110 may be disposed on the gate film GF.

The gate driving circuit 130 may be located only on one side of the display panel 110 or on each of two opposite sides according to driving methods. The gate driving circuit 130 may be implemented in a gate-in-panel GIP) form which is embedded in the bezel area of the display panel 110.

Likewise, one or more source driving integrated circuits SDIC included in the data driving circuit 120 each may be mounted on the source film SF, and one side of the source film SF may be electrically connected with the display panel 110. Lines for electrically connecting the source driver integrated circuit SDIC and the display panel 110 may be disposed on the source film SF.

The display device 100 may include a plurality of source driving integrated circuits SDIC and a printed circuit board for circuit connection between other devices. The printed circuit board may include, e.g., at least one source printed circuit board SPCB and a control printed circuit board CPCB for mounting control components and various electric devices.

In an embodiment, the other side of the source film SF where the source driving integrated circuit SDIC is mounted may be connected to at least one source printed circuit board SPCB. In other words, one side of the source film SF where the source driving integrated circuit SDIC is mounted may be electrically connected with the display panel 110, and the other side thereof may be electrically connected with the source printed circuit board SPCB.

The controller 140 and the power management circuit (power management IC) 150 may be mounted on the control printed circuit board CPCB. The controller 140 may control the operation of the data driving circuit 120 and the gate driving circuit 130. The power management circuit 150 may supply driving voltage or current to the display panel 110, the data driving circuit 120, and the gate driving circuit 130 and control the supplied voltage or current.

At least one source printed circuit board SPCB and control printed circuit board CPCB may be circuit-connected through at least one connection member. The connection member may include, e.g., a flexible printed circuit FPC or a flexible cable (or flexible flat cable).

In this case, the connection member connecting the at least one source printed circuit board SPCB and control printed circuit board CPCB may be varied depending on the size and type of the display device 100. The at least one source printed circuit board SPCB and control printed circuit board CPCB may be integrated into a single printed circuit board.

In the so-configured display device 100, the power management circuit 150 transfers a driving voltage necessary for display driving or characteristic value sensing to the source printed circuit board SPCB through the flexible printed circuit FPC or flexible cable. The driving voltage transferred to the source printed circuit board SPCB is supplied to emit light or sense a specific subpixel SP in the display panel 110 through the source driving integrated circuit SDIC.

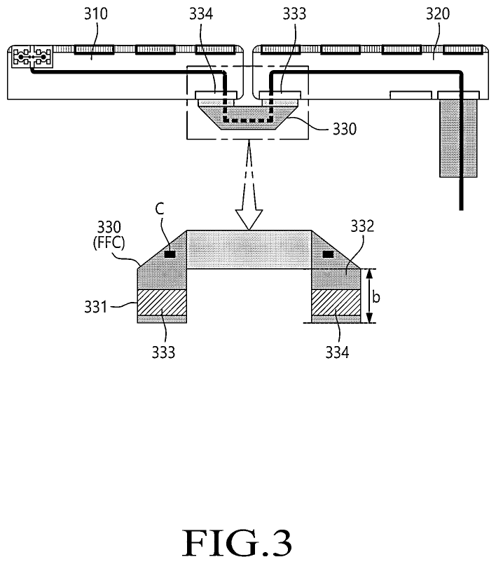

FIG. 3 is a plan view illustrating a flexible cable connecting printed circuit boards.

Referring to FIG. 3, a first printed circuit board 310 and a second printed circuit board 320 may be connected by a flexible cable 330. The flexible cable 330 is one of several types of cables, and any cable capable of connecting the first printed circuit board 310 and the second printed circuit board 320 may also be employed. The first printed circuit board 310 may be a source printed circuit board SPCB, and the second printed circuit board 320 may be a control printed circuit board CPCB.

The types of the first printed circuit board 310 and the second printed circuit board 320 are not limited thereto, and any type of substrate required to exchange signals and power between separated printed circuit boards may be applied.

In an embodiment, the controller of the control printed circuit board CPCB may generate various control signals DCS and GCS to control the data driving circuit and output them to the conductor of the flexible cable 330.

The power management circuit of the control printed circuit board CPCB may output various voltages applied to the data driving circuit and the gate driving circuit to the conductor of the flexible cable 330.

Here, the conductor included in the flexible cable 330 may form a plurality of conducting lines having different widths.

For example, the voltage applied to a relatively narrow conducting line may be a voltage of the data signal DATA or a voltage corresponding to various control signals DCS, GCS, etc. for controlling the data driving circuit and the gate driving circuit.

The voltage applied to a relatively large conducting line may be a driving power supply voltage VDD and a low-potential power supply voltage VSS for driving the display panel 110 and various circuits.

As illustrated in FIG. 3, the flexible cable 330 may be a cable capable of supplying signals and power. The flexible cable 330 may include a conductor 331 and an insulator 332 capable of insulating the conductor 331.

As illustrated in FIG. 3, two opposite end portions 333 and 334 of the insulator 332 which is initially provided in a straight, length direction in the flexible cable 330 may be folded inward or outward by a predetermined angle. In this case, the two opposite end portions 333 and 334 of the flexible cable 330 may be folded to face in the same direction.

Hereinafter, the two opposite end portions 333 and 334 may be referred to as a first bridge 333 and a second bridge 334, respectively, of the flexible cable 330.

As illustrated in FIG. 3, the first bridge 333 of the flexible cable 330 may be connected to at least a portion of the first printed circuit board 310, and the second bridge 334 may be connected to at least a portion of the second printed circuit board 320.

As illustrated in FIG. 3, a flexible flat cable 330 may physically contact the first printed circuit board 310 and the second printed circuit board 320 so that the conductor 331 included in the first bridge 333 and the conductor 335 included in the second bridge 334 are electrically connected to conductors such as signal lines or metal lines of the first printed circuit board 310 and the second printed circuit board 320, respectively.

In other words, the first bridge 333 may be electrically connected to the first printed circuit board 310, and the second bridge 334 may be electrically connected to the second printed circuit board 320, so that the first printed circuit board 310 and the second printed circuit board 320 may be electrically conductive through the flexible cable 330.

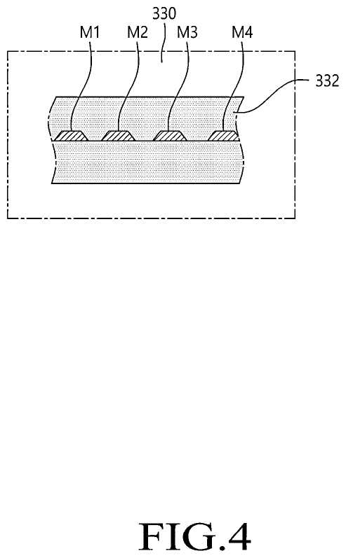

FIG. 4 is a cross-sectional view illustrating a cross section of at least a portion of a flexible cable according to one embodiment.

Referring to FIG. 4, when a cross section of at least a portion of the flexible cable 330 is viewed, a plurality of metal signal lines M1 to M4 spaced apart in the horizontal direction may be provided in a dual insulator 332 provided in dual on the vertical line.

In an embodiment, the plurality of metal signal lines M1 to M4 may be spaced apart from each other by a predetermined interval in the length direction of the flexible cable 330 and may be arranged in the dual insulator 332.

Meanwhile, because various signals are output from the control printed circuit board CPCB to the source printed circuit board SPCB through the cable of the flexible cable 330, impedances of the control printed circuit board CPCB, the source printed circuit board SPCB, and the flexible cable 330 should be designed to match with the same value.

However, since the flexible cable 330 is provided in two layers (double layers) as described above, there is a limitation in matching impedances between printed circuit boards by changing the physical properties of the dielectric or the structure of the dielectric.

For example, when the flexible cable 330 is excessively changed to change the structure of the dielectric, the arrangement of the metal layers provided between the insulators 332 provided as double layers may be disturbed or a short circuit may occur.

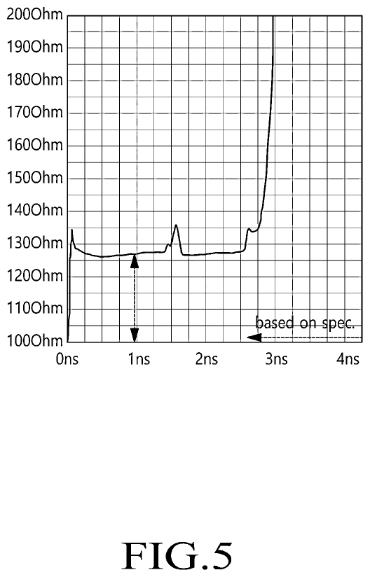

FIG. 5 is a graph illustrating general flexible cable impedance characteristics according to one embodiment.

As illustrated in FIG. 5, when the impedance of the flexible cable does not meet a predetermined specification (e.g., 100Ω), a signal distortion issue due to impedance matching may occur when data is transmitted through the flexible cable.

Further, as flexible cables used in products increase in length with the trend of products being enlarged and diversified, quality influence issues due to impedance matching increase.

Further, since various signals are output from the control printed circuit board CPCB to the source printed circuit board SPCB through the flexible cable, the impedances of the control printed circuit board CPCB, the source printed circuit board SPCB, and the flexible cable 330 should be designed to match with the same value.

Accordingly, during the design process, the control printed circuit board CPCB and the source printed circuit board SPCB are designed to match an impedance value of 1000 in the design process.

While the impedance of the printed circuit board is designed to be 100Ω, the impedance of the flexible cable itself is often as high as 120Ω, so when the printed circuit board and the flexible cable are connected, the impedance of the flexible cable should be adjusted to be close to 100Ω.

Since the impedance of the flexible cable is due to material characteristics, the impedance may be matched by combining the structure proposed in the disclosure with the flexible cable. In other words, since the impedance of the flexible cable is based on material characteristics, the impedance of the flexible cable may be matched to be close to the impedance of the printed circuit board by changing the structure of the flexible cable.

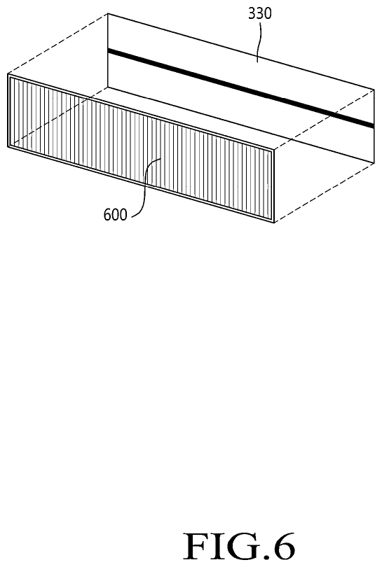

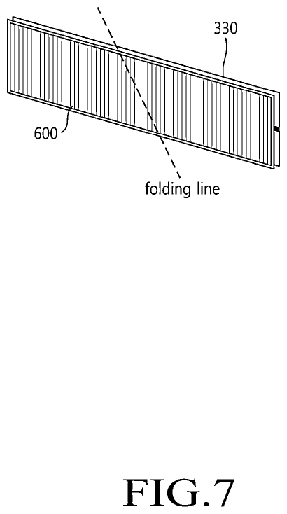

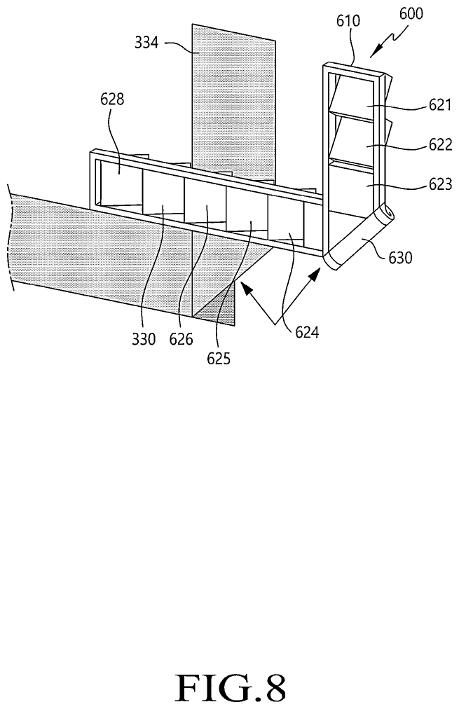

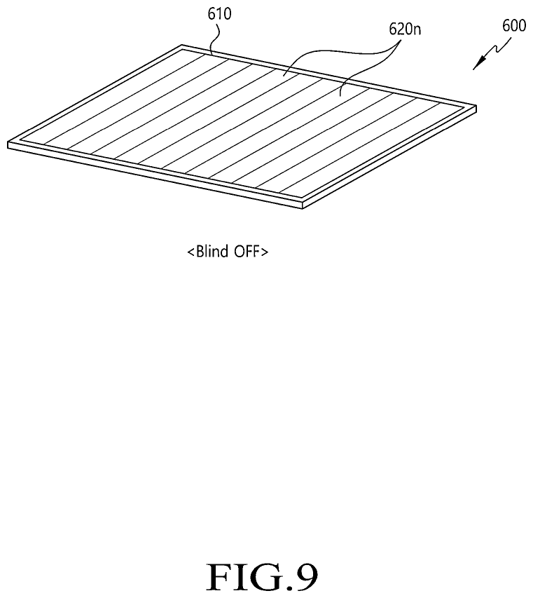

FIG. 6 is a perspective view illustrating an example of a process of attaching a cable impedance matching element and a flexible cable according to an embodiment of the disclosure. FIG. 7 illustrates a state before folding after a cable impedance matching element and a flexible cable are attached according to an embodiment of the disclosure. FIG. 8 is a perspective view illustrating a coupling structure between a cable impedance matching element and a flexible cable according to an embodiment of the disclosure. FIG. 9 is a plan view illustrating a cable impedance matching element in a blind-off state according to an embodiment of the disclosure.

Referring to FIGS. 6 and 7, a flexible cable 330 according to an embodiment of the disclosure may be coupled to a cable impedance matching element 600 by front attachment. In this case, the front attachment coupling may be performed through a double-sided tape, an adhesive, a screw fastening structure, a fitting fastening structure, or the like. Alternatively, in the process of manufacturing the flexible cable 330, the cable impedance matching element 600 and the flexible cable 330 may be thermally bonded to each other while removing an empty space between the two components.

Referring to FIG. 8, the cable impedance matching element 600 may include a blind frame 610 that supports the impedance matching element 600. The outline of the blind frame 610 may be provided in the same shape as the flexible cable 330 along the outer circumferential shape of the flexible cable 330, or may have a polygonal outer shape such as a square, a pentagon, or the like, but is not limited thereto.

Referring to FIG. 9, the cable impedance matching element 600 may be provided by coupling a plurality of respective blind blades 620n between at least one side and the other side of the edge of the blind frame 610.

Specifically, the plurality of blind blades 620 may be provided to be rotatable at a predetermined angle by being spaced apart from each other at a predetermined interval between the left edge frame and the right edge frame of the blind frame 610.

Referring to FIGS. 8 and 9, two opposite ends of each blind blade 621 to 628 may be coupled to the left and right frames, respectively, so as to be rotatable between the left and right frames. To that end, various fastening methods may be used, such as press-fitting or screwing to each of the blind blades 621 to 628 and at least a portion of the blind frame 610.

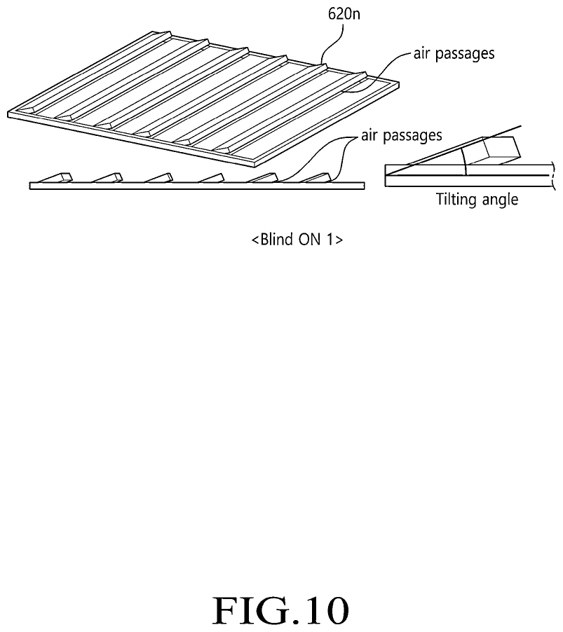

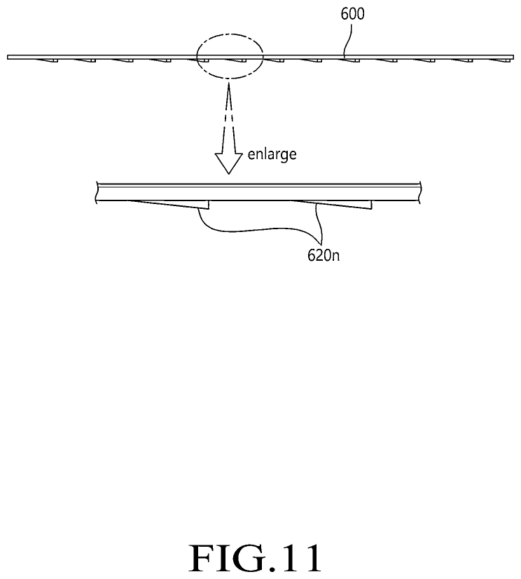

FIG. 10 is a plan view and a side view illustrating a cable impedance matching element in a blind-on state according to an embodiment of the disclosure. FIG. 11 is a partially enlarged side view illustrating a cable impedance matching element in a blind-on state according to an embodiment of the disclosure.

As illustrated in FIGS. 9 and 10, each of the blind blades 621 to 628 may allow the air passage inside the blind frame 610 to be opened and closed by rotating at a predetermined angle, i.e., tilting. The air passage refers to a space formed between the blind blade 620n and the cable facing the blind blade 620n.

To that end, the blind blade 620n may be provided in the form of two or more bars in which the tilting angle is adjusted inside the blind frame 610. The distance or angle between the blind blade 620n and the cable facing the blind blade 620n may be controlled through tilting control. For example, when tilting is controlled so that the angle between the blind blade 620n and the flexible cable 330 facing the blind blade 620n becomes 0, the air passage between the blind blade 620n and the flexible cable 330 facing the blind blade 620n is closed, and thus the air layer formed in the air passage is absent.

In other words, when the blind blade 620n is rotated at a predetermined angle by the tilting control to cover the flat surface of the flexible cable 330 facing the blind blade 620n, the air passage between the blind blade 620n and the cable is closed.

Referring to FIGS. 10 and 11, the inclined angle of the blind blade 620n may be defined as a tilting angle.

When the tilting angle is 0 degrees, it may be defined as a blind-off state, and when the tilting angle is a predetermined angle other than 0 degrees, it may be defined as a blind-on state.

At this time, as illustrated in FIG. 9, when all of the blind blades 620n cover the plane of the flexible cable 330 facing the blind blades 620n by the tilting control, the air passage is closed, and thus the air layer formed in the air passage between the blind blades 620n and the flexible cable 330 is absent.

Conversely, as illustrated in FIG. 10, when the blind blade 620n is rotated at a predetermined angle by the tilting control to generate a gap between the blind blade 620n and the cable facing the blind blade 620n, an air passage may be formed between the blind blade 620n and the flexible cable 330 facing the blind blade 620n, and the air layer generated by the air passage may be maintained.

Here, the blind blades 620n may close or maintain the air passage inside the blind frame 610 for each blind section grouped into two or more blind blades 620n. The number of the grouped blind blades 620n may be more than one.

In an embodiment of the disclosure, the display controller 140 may determine to close or maintain the air passage by the blind blades 620n constituting the cable impedance matching element according to a capacitance value required in a flexible flat cable structure, and may determine the tilting angle of the blind blades 620n.

Here, the tilting angle of the blind blades 620n may be determined by the display controller 140, and the angle control of the blind blades 620n may be performed through an automation system based on electric power. To that end, the display controller 140 and the power components tilting the blind blades 620n may be electrically connected to each other.

Alternatively, the tilting angle of the blind blades 620n may be determined by the display controller 140, and the angle control of the blind blades 620n may be performed by a manual operation of the designer. To that end, the display controller 140 may detect and provide impedance change information about the flexible cable 330 in real time according to a change in the tilting angle of the blind blades 620n.

The blind frame 610 may be coupled to the flexible cable 330 along the length direction of the flexible cable 330.

The cable impedance matching element 600 may include an internal conductor and an insulating material surrounding the conductor.

For example, the component of the cable impedance matching element 600 may be formed of poly lactic acid (PLA), acrylonitrile butadiene styrene (ABS), or the like, which are thermoplastic resins having a permittivity of 2.7 to 3. The cable impedance matching element 600 may be manufactured through 3D printing or FDM printing, but is not limited thereto.

As described above with reference to FIGS. 6 and 7, the flexible cable 330 and the cable impedance matching element 600 may be provided in such a manner that they are front-attached while being unfolded and, then, their end portions are partially folded to form bridges 333 and 334, respectively, at their ends.

Alternatively, as illustrated in FIGS. 3 and 8, a portion of the cable impedance matching element 600 may be press-fitted into the flexible cable 330 having bridges 333 and 334 pre-formed as two opposite ends are partially folded.

To that end, the blind frame 610 may be press-fitted into the folded portion of the flexible cable 330 with its portion 630 folded corresponding to the folded portion of the flexible cable 330.

Specifically, a portion of the blind frame 610 may be coupled or attached in the length direction of the body of the flexible cable 330, and the hinge portion 630 of the blind frame 610 may be inserted into an inner space formed as the portion between the body of the flexible cable 330 and the bridge 334 is folded. The end of the blind frame 610 may be coupled or attached in the length direction of the bridge 334 of the flexible cable 330.

In the cable impedance matching element 600, the tilting angle of the blind blade 620 may be changed under the control of the display controller 140 according to the capacitance required for the flexible cable 330.

Here, the capacitance required for the flexible cable 330 may be the capacitance C required to decrease the impedance (reactance) when the capacitance is C and the on resistance (reactance) by the capacitance is ZC in Equation 1 regarding capacitance as follows. In other words, the capacitance corresponding to the impedance to be decreased in the flexible cable 330 may be defined as the capacitance required for the flexible cable 330.

As mentioned above, for example, the capacitance required for the flexible cable to match the impedance of the flexible cable which has relatively higher impedance than the printed circuit board on its own to the impedance of the printed circuit board when connecting the printed circuit board and the flexible cable is obtained through the impedance matching element 600.

Z_{C}=1/jωC Equation 1

Referring to FIGS. 8 to 10, the cable impedance matching element 600 may change the permittivity of the flexible cable 330 by controlling the tilting angle of the blind blades 620n through the controller 140.

To that end, the volume of the air layer between the blind blades 620n and the flexible cable 330 facing the blind blades 620n may be adjusted by controlling the tilting angle of the blind blades 620n to open or close the air passage by the blind blades 620n or by adjusting the degree to which the air passage is opened. As described above, as the volume of the air layer between the blind blade 620n and the flexible cable 330 facing the blind blade 620n is adjusted, the permittivity characteristic of the flexible cable 330 may be changed.

By changing the permittivity characteristic of the flexible cable 330 in a state in which the cable impedance matching element 600 is coupled to the flexible cable 330, the capacitance required for the flexible cable 330 may be generated to reduce the reactance (impedance) of the flexible cable 330. Accordingly, it is possible to adjust the impedance of the flexible cable itself having a higher impedance than that of the printed circuit board to be close to the impedance of the printed circuit board.

The blind frame 610 may fix the hinge portion 630 to the space generated by folding the flexible cable 330 through fitting fastening, thereby fixing and keeping in shape the cable impedance matching element 600 to the flexible cable 330 simply only with a press-fitting structure without using a tape, an adhesive, or the like. Thus, it is possible to minimize or at least reduce a change in impedance that is caused unintentionally by a fixing method using a tape or an adhesive.

The blind frame 610 may be coupled to at least a portion of the flexible cable 330 by further using screw fastening together with the above-described fitting structure.

The cable impedance matching element 600 may decrease the reactance of the flexible cable 330 by obtaining the capacitance required for the flexible cable 330 according to the adjustment of the tilting angle of the blind blade 620, thereby impedance-matching with the printed circuit board to be connected.

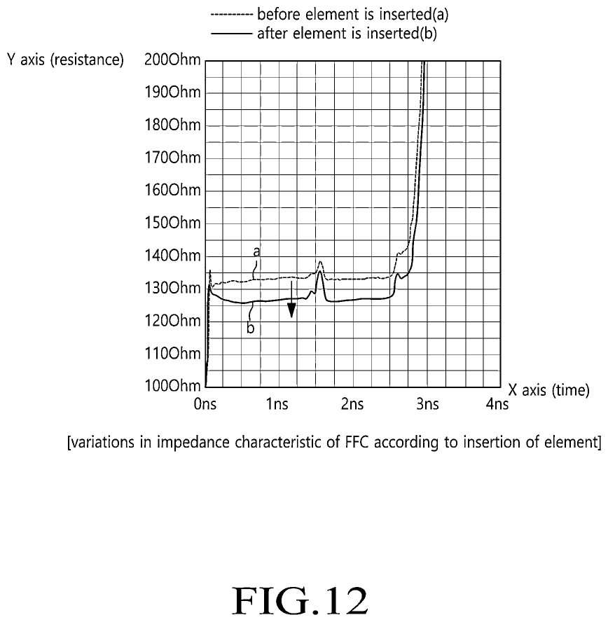

FIG. 12 is a graph illustrating a change in impedance characteristics of a flexible cable including a cable impedance matching element.

The graph of FIG. 12 illustrates changes in impedance characteristics of the flexible cable before (a) and after (b) the hinge area of the cable impedance matching element is inserted into the folding area of the flexible cable, among the above-described embodiments.

The impedance (a) of the flexible cable into which the cable impedance matching element according to an embodiment of the disclosure is not inserted maintains a state in which the impedance by the structure itself is higher than the printed circuit board to be matched.

On the other hand, it may be identified that the impedance (b) of the flexible cable into which the cable impedance matching element according to an embodiment of the disclosure is inserted is slightly lower than (a) so as to be close to the impedance of the printed circuit board to be matched.

This is due to the change in the permittivity of the flexible cable 330 through the control of the tilting angle for the blind blades 620n constituting the cable impedance matching element coupled to the flexible cable.

The permittivity characteristic of the flexible cable may be changed by a change in the volume of the air layer formed between the blind blades 620n and the flexible cable faced by the blind blades 620n as the tilting angle formed with the flexible cable faced by the blind blades 620 is controlled and, by using such principle, the capacitance required for the flexible cable to match the impedance of the flexible cable to the impedance of the printed circuit board to be connected may be generated.

In an embodiment, the tilting angle of the plurality of blind blades 620n may be controlled by the display controller 140 according to the capacitance required for the flexible cable 330, and the tilting angle may be controlled to be different for each number of blind blades 620n. In other words, among the blind blades 620n, a first group of blind blades of a predetermined number may be tilted at a first angle, a second group of blind blades of a predetermined number may be tilted at a second angle, and a third group of blind blades of a remaining number may be tilted at a third angle.

For example, half of the plurality of blind blades 620n may be turned to the blind-off state as the tilting angle is controlled to be 0, and the other half may be turned to the blind-on state as the tilting angle is controlled to be a predetermined angle other than 0. In this case, the tilting angle of the blind blades of which the tilting angle is not 0 may be controlled for each blind blade.

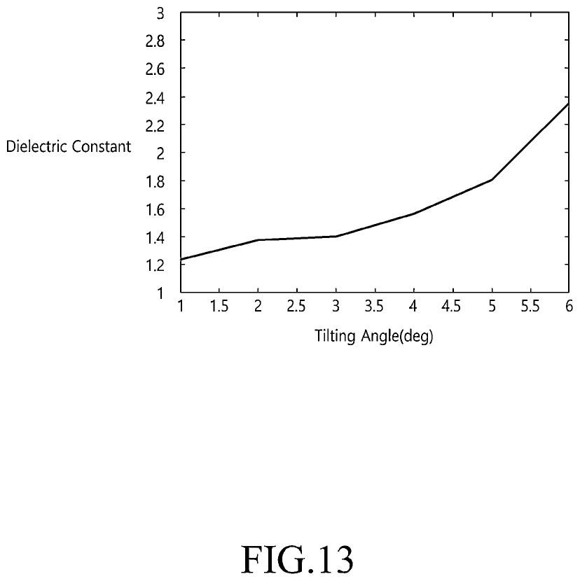

FIG. 13 is a graph illustrating a change in permittivity of a flexible cable according to a tilting angle in a blind-on state.

Referring to FIGS. 10 and 13, when the blind blades 620n are in the blind-on state as their tilting angles all are predetermined angles other than 0, it may be identified that the permittivity of the flexible cable increases in proportion to the tilting angle of the blind blades 620n.

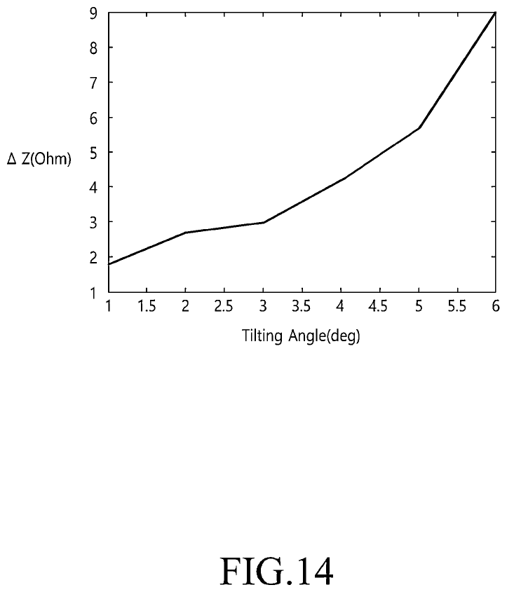

FIG. 14 is a graph illustrating an impedance variation width of a flexible cable according to a tilting angle in a blind-on state of blind blades.

Referring to FIGS. 10 and 14, when the blind blades 620n are in the blind-on state as their tilting angles are predetermined angles other than 0, it may be identified that the width of the impedance variation increases in proportion to the tilting angle of the blind blades 620n.

According to embodiments of the disclosure, it is possible to match the impedance of the flexible cable to be close to the impedance of the printed circuit board to be connected, by changing the permittivity characteristic of the flexible cable by having a cable impedance matching element in the flexible cable.

According to embodiments of the disclosure, it is possible to safely and simply match the impedance of the flexible cable to the impedance of the printed circuit board to be connected without negative influence on the arrangement of metal layers provided in the flexible cable by providing an impedance matching element capable of adjusting the impedance of the flexible cable by controlling the tilting angle of blind blades to the flexible cable.

According to embodiments of the disclosure, it is possible to achieve accurate impedance matching by being able to control the tilting angle of the plurality of blind blades per number of blind blades or per angle of blind blade according to the capacitance required for the flexible cable.

According to embodiments of the disclosure, it is possible to fix and keep in shape the impedance matching element in the flexible cable simply with a press-fitting structure without using a table or adhesive, by press-fittingly fixing a hinge portion of a blind frame in a space formed as the flexible cable is folded. Thus, it is possible to minimize a change in impedance that is caused unintentionally by a fixing method.

Embodiments of the disclosure described above are briefly described below.

A cable impedance matching element according to an embodiment of the disclosure may comprise a blind frame coupled to the cable and supporting the cable impedance matching element, and a plurality of blind blades provided between at least one side and another side of an edge of the blind frame to be spaced apart from each other by a predetermined interval, and coupled to be rotatable between the one side and the other side of the blind frame. The blind blades may have an angle from the cable facing the blind blades determined while being rotated through tilting control.

The blind frame is coupled or attached to the cable along a length direction of the cable.

The blind frame have a hinge portion press-fittingly fastened into an inner space formed by folding between a body of the cable and a bridge.

The blind blades are tilting-controlled according to a capacitance required for the cable to match an impedance of the cable to an impedance of a printed circuit board to which the cable is to be connected.

The blind blades are turned to a blind-off state to close an air passage between the blind blades and the cable when a tilting angle with respect to the facing cable is 0.

The blind blades are turned to a blind-on state to form an air passage between the blind blades and the cable when a tilting angle with respect to the facing cable is not 0.

The blind blades have a tilting angle controlled to be different for each number of the blind blades according to a capacitance required for the cable to match an impedance of the cable to an impedance of a printed circuit board to which the cable is to be connected.

The cable impedance matching element is formed of poly lactic acid (PLA) or acrylonitrile butadiene styrene (ABS), which is a thermoplastic resin having a permittivity of 2.7 to 3.

A display device according to an embodiment of the disclosure may comprise a display panel where a plurality of data lines and a plurality of gate lines are disposed, and a first printed circuit board supplying a voltage to a data driving circuit driving the data line and a gate driving circuit driving the gate line, a second printed circuit board electrically connected to the first printed circuit board to supply a signal for driving the data driving circuit and the gate driving circuit and a common voltage for driving the panel, and a cable connecting the first printed circuit board and the second printed circuit board. The cable may include a cable impedance matching element to match an impedance of the cable with impedances of the first printed circuit board and the second printed circuit board.

According to embodiments of the disclosure described above, there may be provided a cable impedance matching element and a display device including the same.

According to embodiments of the disclosure, it is possible to match the impedance of the flexible cable to be close to the impedance of the printed circuit board to be connected, by changing the permittivity characteristic of the flexible cable by having a cable impedance matching element in the flexible cable.

According to embodiments of the disclosure, it is possible to implement a simplified driving scheme for impedance matching without negative influence on the arrangement of metal layers provided in the flexible cable by providing an impedance matching element capable of adjusting the impedance of the flexible cable by controlling the tilting angle of blind blades to the flexible cable.

According to embodiments of the disclosure, it is possible to achieve accurate impedance matching by being able to control the tilting angle of the plurality of blind blades per number of blind blades according to the capacitance required for the flexible cable.

According to embodiments of the disclosure, it is possible to press-fittingly fix the hinge portion of the blind frame to a space formed as the flexible cable is folded. In other words, it is possible to fix and keep in shape the impedance matching element to the flexible cable simply with a press-fitting structure even without using, e.g., a tape or an adhesive. Thus, it is possible to minimize a change in impedance that is caused unintentionally by a fixing method using a tape or an adhesive.

According to embodiments of the disclosure, it is possible to maintain communication quality while preventing distortions of signal form by impedance matching between elements and mitigating a difference in impedance between elements.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed is:

1. A cable impedance matching element provided in a cable, comprising:
a blind frame coupled to the cable and supporting the cable impedance matching element; and
a plurality of blind blades between at least one side and another side of an edge of the blind frame to be spaced apart from each other by a predetermined interval, the plurality of blind blades coupled to be rotatable between the at least one side and the other side of the blind frame,
wherein the plurality of blind blades have an angle from the cable facing the plurality of blind blades determined while being rotated through tilting control.

2. The cable impedance matching element of claim 1, wherein the blind frame is coupled or attached to the cable along a length direction of the cable.

3. The cable impedance matching element of claim 2, wherein the blind frame has a hinge portion press-fittingly fastened into an inner space formed by folding between a body of the cable and a bridge.

4. The cable impedance matching element of claim 1, wherein the plurality of blind blades are tilting-controlled according to a capacitance to match an impedance of the cable to an impedance of a printed circuit board to which the cable is connected.

5. The cable impedance matching element of claim 4, wherein the plurality of blind blades are turned to a blind-off state that close an air passage between the plurality of blind blades and the cable when a tilting angle with respect to the facing cable is 0.

6. The cable impedance matching element of claim 4, wherein the plurality of blind blades are turned to a blind-on state that form an air passage between the plurality of blind blades and the cable when a tilting angle with respect to the facing cable is not 0.

7. The cable impedance matching element of claim 4, wherein the plurality of blind blades have a tilting angle controlled to be different for each number of the plurality of blind blades according to a capacitance to match an impedance of the cable to an impedance of a printed circuit board to which the cable is to be connected.

8. The cable impedance matching element of claim 1, wherein the cable impedance matching element includes poly lactic acid (PLA) or acrylonitrile butadiene styrene (ABS), which is a thermoplastic resin having a permittivity of 2.7 to 3.

9. A display device, comprising:
a display panel including a plurality of data lines and a plurality of gate lines; and
a first printed circuit board supplying a voltage to a data driving circuit driving a data line from the plurality of data lines and a gate driving circuit driving a gate line from the plurality of gate lines;
a second printed circuit board electrically connected to the first printed circuit board and supplies a signal that drives the data driving circuit and the gate driving circuit and a common voltage that drives the display panel; and
a cable connecting the first printed circuit board and the second printed circuit board,
wherein the cable includes a cable impedance matching element that matches an impedance of the cable with impedances of the first printed circuit board and the second printed circuit board.

10. The display device of claim 9, wherein the cable impedance matching element includes:
a blind frame coupled to the cable and supporting the cable impedance matching element; and
a plurality of blind blades between at least one side and another side of an edge of the blind frame to be spaced apart from each other by a predetermined interval, and coupled to be rotatable between the at least one side and the other side of the blind frame,
wherein the plurality of blind blades have an angle from the cable facing the plurality of blind blades determined while being rotated through tilting control.

11. The display device of claim 10, wherein the blind frame is coupled or attached to the cable along a length direction of the cable.

12. The display device of claim 11, wherein the blind frame has a hinge portion press-fittingly fastened into an inner space formed by folding between a body of the cable and a bridge.

13. The display device of claim 10, wherein the plurality of blind blades are tilting-controlled according to a capacitance that matches an impedance of the cable to an impedance of a printed circuit board to which the cable is to be connected.

14. The display device of claim 13, wherein the plurality of blind blades are turned to a blind-off state and close an air passage between the plurality of blind blades and the cable when a tilting angle with respect to the facing cable is 0.

15. The display device of claim 13, wherein the plurality of blind blades are turned to a blind-on state and form an air passage between the plurality of blind blades and the cable when a tilting angle with respect to the facing cable is not 0.

16. The display device of claim 13, wherein the plurality of blind blades have a tilting angle controlled to be different for each number of the plurality of blind blades according to a capacitance that matches an impedance of the cable to an impedance of a printed circuit board to which the cable is to be connected.
